(19) United States
(12) Patent Application Publication
(10) Pub. No.: US 2025/0168931 A1
(43) Pub. Date: May 22, 2025

(54) HIGH-POWER HIGH-FREQUENCY ELECTRIC HEATING SYSTEM FOR LASER OPTICAL PUMP ATOMIC MAGNETOMETER

(71) Applicant: Beihang University, Beijing (CN)

(72) Inventors: Shiqiang ZHENG, Beijing (CN); Ximing LIU, Beijing (CN); Lian REN, Beijing (CN); Yuxuan LI, Beijing (CN); Jin LI, Beijing (CN)

(21) Appl. No.: 19/023,864

(22) Filed: Jan. 16, 2025

Related U.S. Application Data
(63) Continuation of application No. PCT/CN2024/129606, filed on Nov. 4, 2024.

(30) Foreign Application Priority Data
Nov. 22, 2023 (CN) 202311562356.X

(51) Int. Cl. H05B 3/00; H05B 1/02

(52) U.S. Cl. CPC H05B 3/0019; H05B 1/0202

(57) ABSTRACT

A high-power high-frequency electric heating system for a laser optical pump atomic magnetometer is provided, including an oscillation generating module, a temperature detecting module, a control module, a power output module and a coil heating module; wherein the oscillation generating module is used for transmitting 1 MHz oscillation signals; the temperature detecting module is used for measuring temperature of the alkali metal gas chamber to obtain differential voltage; the control module performs an amplitude modulation on the 1 MHz oscillation signals based on the differential voltage to obtain 1 MHz oscillation signals after the amplitude modulation; the power output module is used for performing voltage amplifying on the 1 MHz oscillation signals after the amplitude modulation and inputting the 1 MHz oscillation signals after the amplitude modulation to the coil heating module; the coil heating module is used for heating alkali metal gas chamber based on received voltage.

### CROSS-REFERENCE TO RELATED APPLICATIONS

This application is a continuation of PCT/CN2024/129606, filed on Nov. 4, 2024 and claims priority of Chinese Patent Application No. 202311562356.X, filed on Nov. 22, 2023, the entire contents of which are incorporated herein by reference.

### TECHNICAL FIELD

The disclosure relates to the field of high-frequency electric heating circuits, in particular to a high-power high-frequency electric heating system for a laser optical pump atomic magnetometer.

### BACKGROUND

Laser optical pump atomic magnetometer, as a new type of atomic magnetometer, including optical pump magnetometer and NMOR magnetometer, has a broad application prospect in high sensitivity and high precision detection in geomagnetic environment. The principle of measuring the magnetic field is that the magnetic moment of alkali metal atoms is generated by splitting the packed energy level, and then Larmor precession is generated. The frequency of Larmor precession is proportional to the external magnetic field, and the magnetic field may be measured by the precession of atoms.

When the laser optical pump atomic magnetometer works, it is necessary not only to heat the temperature of the alkali metal gas chamber to a certain temperature to ensure the alkali metal gasification to achieve the atomic density required for Zeeman level splitting, but also to ensure that it does not introduce the magnetic field interference of Larmor precession frequency and modulation frequency within the measurement range of the optical pump magnetometer, and to ensure the heating control accuracy and a certain heating power. In order to ensure the integration and miniaturization of the optical pump magnetometer, it is necessary to limit the volume of the heating device.

At present, there are five main heating modes for the gas chamber of laser optical pump atomic magnetometer, namely, airflow heating method, intermittent heating method, bidirectional current heating method, high-frequency electric heating method and laser heating method. The temperature control accuracy of the airflow heating method is low, and the volume of heating device is large, which is not conducive to the integration and miniaturization of optical pump magnetometer, and there is airflow interference; although the temperature control accuracy of the intermittent heating method is slightly higher than that of the airflow heating method, it is impossible to measure the continuous magnetic field because of the discontinuous heating process; laser heating method has high temperature control accuracy, but the heating power is small, and an optical path is added, which is not conducive to the integration and miniaturization of optical pump magnetometer; bidirectional current heating may counteract each other's magnetic fields by adjusting the arrangement of heating film circuits, but using direct current heating will introduce white noise and low-frequency noise, which will have a great influence on the Larmor precession frequency of the gas chamber.

### SUMMARY

In order to solve the technical problems in the above background, the present disclosure is eager to propose a heating device which may keep the output power of electric heating at high frequency, and at the same time, the linear power amplifier device has strong high-frequency loading capacity.

In order to achieve the above objective, the disclosure provides a high-power high-frequency electric heating system for a laser optical pump atomic magnetometer, which is used for heating an alkali gas chamber of the laser optical pump atomic magnetometer, including an oscillation generating module, a temperature detecting module, a control module, a power output module and a coil heating module;
where the oscillation generating module is used for transmitting 1 MHz oscillation signals;
the temperature detecting module is used for measuring a temperature of the alkali metal gas chamber to obtain a differential voltage;
the control module performs an amplitude modulation on the 1 MHz oscillation signals based on the differential voltage to obtain 1 MHz oscillation signals after the amplitude modulation;
the power output module is used for performing voltage amplifying on the 1 MHZ oscillation signals after the amplitude modulation and inputting the 1 MHz oscillation signals after the amplitude modulation to the coil heating module; and
the coil heating module is used for heating the alkali metal gas chamber based on a received voltage.

Optionally, the oscillation generating module includes a 1 MHz oscillation signal source, a follow-up amplitude modulation circuit and a band-pass filter;
where the 1 MHz oscillation signal source is used for transmitting the 1 MHz oscillation signals;
the follow-up amplitude modulation circuit adjusts an amplitude of the 1 MHZ oscillation signals; and
the band-pass filter is used for filtering the 1 MHz oscillation signals.

Optionally, the temperature detecting module includes a constant current source transmitting device, a four-wire system pt1000 temperature detector and an instrument amplifier resistance detector; the four-wire system pt1000 temperature detector is respectively connected with the constant current source transmitting device and the instrument amplifier resistance detector.

Optionally, a work flow of the temperature detecting module includes: transmitting a constant current source by using the constant current source transmitting device and connecting to the four-wire system pt1000 temperature detector, eliminating the line resistance error by using a four-wire system, and finally differentially amplifying the voltages at both ends of the four-wire system pt1000 temperature detector by using the instrument amplifier resistance detector to obtain the differential voltage, thus completing a measurement of an air chamber temperature.

Optionally, the control module includes an analog-to-digital converter, a controller, a digital-to-analog converter and a voltage-controlled gain amplifier; the controller is respectively connected with the analog-to-digital converter and the digital-to-analog converter; and the digital-to-analog converter is respectively connected with the voltage-controlled gain amplifier and the analog-to-digital converter.

Optionally, a work flow of the control module includes: the differential voltage is analog-to-digital converted by the analog-to-digital converter and then input into the controller; after being processed by the controller, a control quantity is converted into temperature control signals by the digital-to-analog converter to input into the voltage-controlled gain amplifier to complete a closed-loop control; and the voltage-controlled gain amplifier performs an amplitude modulation on the 1 MHz oscillation signals based on the temperature control signals.

Optionally, the power output module includes four identical high-frequency power amplifiers, which are used to amplify the voltage of the 1 MHz oscillation signals after the amplitude modulation and ensure the output power is stable when loaded.

Optionally, the power output module further completes a maximum voltage output and a maximum current output twice a maximum voltage output and a maximum current output under a rated bandwidth of the high-frequency power amplifiers through a topological circuit.

Compared with the prior art, the disclosure has the following beneficial effects.

The disclosure ensures the stability of output frequency through the oscillation source of the oscillation signal generating circuit; at the same time, the topological structure is used to improve the output voltage and current range of the heating system, reduce the output power requirement of the high-frequency power amplifier, improve the frequency of high-frequency electric heating while ensuring the output power, and further improve the magnetic measurement range of the optical pump magnetometer.

### BRIEF DESCRIPTION OF THE DRAWINGS

In order to explain the technical scheme of the present disclosure more clearly, the drawings needed in the embodiments are briefly introduced below. Obviously, the drawings in the following description are only some embodiments of the present disclosure. For ordinary people in the field, other drawings may be obtained according to these drawings without paying creative labor.

FIG. 1 is a schematic diagram of the structural framework of an embodiment of the present disclosure.

FIG. 2 is a control block diagram of an embodiment of the present disclosure.

FIG. 3 is a schematic structural diagram of a 1 MHz oscillation signal source according to an embodiment of the present disclosure.

FIG. 4 is a schematic structural diagram of a power output module according to an embodiment of the present disclosure.

### DETAILED DESCRIPTION OF THE EMBODIMENTS

In the following, the technical scheme in the embodiment of the disclosure will be clearly and completely described with reference to the attached drawings. Obviously, the described embodiments are only a part of the embodiment of the disclosure, but not the whole embodiments. Based on the embodiments in the present disclosure, all other embodiments obtained by ordinary technicians in the field without creative labor belong to the scope of protection of the present disclosure.

In order to make the above objects, features and advantages of the present disclosure more obvious and easy to understand, the present disclosure will be further described in detail with the attached drawings and specific embodiments.

Before the explanation, first introduce the current mainstream air chamber heating methods. The high-frequency electric heating method has high heating power and high temperature control accuracy, and it is far away from the frequency range of magnetic modulation or optical modulation of laser optical pump atomic magnetometer by increasing the working frequency, thus avoiding the magnetic field interference within the measurement range, which is suitable for the integration and miniaturization of laser optical pump atomic magnetometer.

The frequency of magnetic modulation or optical modulation is related to the Larmor precession frequency, and the formula of Larmor precession frequency is:

$${ω}_{L} = γ {B}_{0}$$

where ω_{L} is the Larmor precession frequency; γ is the gyromagnetic ratio of the gas chamber atoms, which is a constant value, and is related to the types of gas chamber atoms. The value of potassium atom is about 7 Hz/nT, and the value of helium atom is about 28 Hz/nT. B₀ is the external magnetic field to be measured. In the case of geomagnetic field, B₀ is about 50000 nT.

Taking potassium atom optical pump magnetometer and potassium atom NMOR magnetometer as examples, the potassium atom optical pump magnetometer measures Larmor precession by detecting the intensity change of transmitted light passing through the gas chamber, so it is necessary to use a modulated magnetic field for magnetic resonance, and the frequency requirements are: ω_{rf}=ω_{L}, according to the formula for calculating Larmor precession frequency, the modulation frequency is about 350 kHz in geomagnetic environment; when the potassium atom NMOR magnetometer measures the Larmor precession frequency through the change of optical rotation angle, it is necessary to use the intensity of linearly polarized light modulated into the gas chamber to generate a strong resonance curve, and the frequency requirement is: ωₘ=2ω_{L}. According to the formula for calculating the Larmor precession frequency, the modulation frequency is about 700 kHz in geomagnetic environment.

Therefore, at present, high-power high-frequency electric heating equipment above 1 MHz is needed to heat the gas chamber of laser optical pump atomic magnetometer.

However, it is difficult to realize the function, especially to maintain the output power of electric heating at high frequency from 500 kHz to 1 MHZ, which requires high gain bandwidth product and slew rate of the output devices. This kind of devices often have voltage output limitations, and the linear power amplifier device has poor high-frequency band loading ability, which leads to the maximum output voltage and current value may not meet the design requirements at high frequency. At present, there are no commercial devices suitable for 4W high power output at the frequency of 1 MHz in the market.

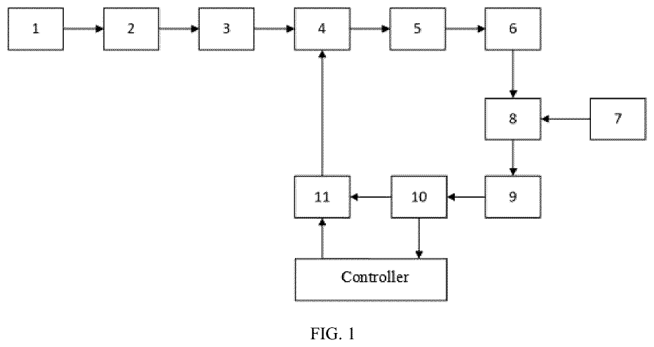

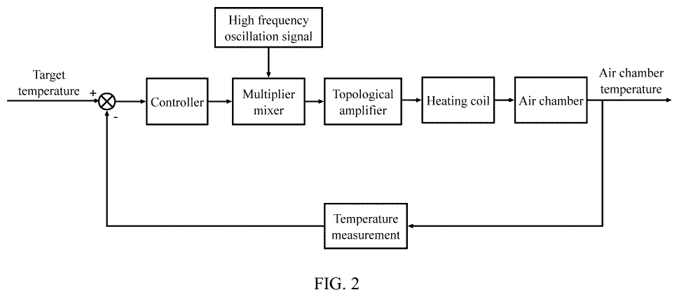

Based on the defects of the above mainstream heating method, this embodiment designs a high-power high-frequency electric heating system for a laser optical pump atomic magnetometer, as shown in FIG. 1, which includes an oscillation generating module, a temperature detecting module, a control module, a power output module and a coil heating module; the oscillation generating module is used for transmitting 1 MHz oscillation signals;
the temperature detecting module is used for measuring a temperature of the alkali metal gas chamber to obtain a differential voltage; the control module performs an amplitude modulation on the 1 MHz oscillation signals based on the differential voltage to obtain 1 MHz oscillation signals after the amplitude modulation; the power output module is used for performing voltage amplifying on the 1 MHz oscillation signals after the amplitude modulation and inputting the 1 MHz oscillation signals after the amplitude modulation to the coil heating module; the coil heating module is used for heating the alkali metal gas chamber based on a received voltage; and the control block diagram of the system is shown in FIG. 2.

The specific structural components of each part of the present disclosure will be described in detail in connection with this embodiment.

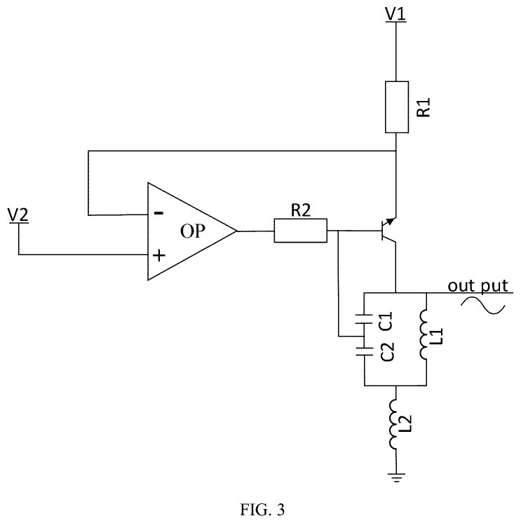

The oscillation generating module includes a 1 MHz oscillation signal source 1, a follow-up amplitude modulation circuit 2 and a band-pass filter 3. The specific structure of the 1 MHz oscillation signal source 1 is shown in FIG. 3. Among them, L₁, C₁, and C₂ constitute the LC resonant tank. When the circuit is working, C, and C₂ are charged and discharged by L₁ after the capacitor is fully charged, so as to achieve the objective of oscillation signal starting. The high-precision and low-noise operational amplifier OP ensures the constant voltage at both ends of R₁ through the voltage follow-up structure, and R is a high-precision resistor, so the current through R₁ is:

$${I}_{1} = \frac{{V}_{1} - {V}_{2}}{{R}_{1}} = {I}_{E}$$

where I₁ is the current through R₁, V₁ and V₂ are the input voltages, IF is the emitter current of the P-channel triode, and

$${U}_{E} = {V}_{2}$$

where U_{E} is the emitter voltage of the triode.

Therefore, the emitter current and emitter voltage through the triode may be changed by changing the input voltages V₁ and V₂, and the amplification bias point of the triode and the amplitude voltage when the oscillation is stable may be changed.

L₁, C₁, C₂ and triode form a feedback amplification loop, and the feedback quantity is amplified by triode co-injection amplification to ensure the stability of oscillation amplitude, and finally an unbiased stable sine wave with a frequency of 1 MHz is formed. L₂ is used to isolate the ground and the oscillation circuit, prevent the oscillation signal from being introduced into the ground, and provide the discharge circuit for C₁, and C₂, which is beneficial to the oscillation of LC resonant tank. Because the oscillation signal source has no load capacity, it is necessary to add the follow-up amplitude modulation circuit 2 to ensure the load capacity and the subsequent output is not distorted; at the same time, the operational amplifier is used to amplify the oscillation signal in proportion, so that the amplitude of the oscillation signal may meet the subsequent requirements; finally, in order to eliminate the influence of noise in the oscillation signal, the band-pass filter 3 is used to filter the oscillation signal.

The temperature detecting module includes a constant current source transmitting device 7, a four-wire system pt1000 temperature detector 8 and an instrument amplifier resistance detector 9. The constant current source transmitting device 7 provides a constant-current source with an output accuracy of 1 uA, and is connected to the four-wire system pt1000 temperature detector 8. The line resistance error is eliminated by the four-wire system, and the voltages at both ends of the four-wire system pt1000 temperature detector 8 are differentially amplified by the instrument amplifier resistance detector 9 to obtain an output voltage (differential voltage) which is linear with the temperature, thus completing the measurement of the air chamber temperature.

The control module includes an analog-to-digital converter 10, a controller, a digital-to-analog converter 11 and a voltage-controlled gain amplifier 4. After the differential voltage obtained by the temperature measuring module is subjected to analog-to-digital conversion by the analog-to-digital converter 10, and then input into the controller, and the error value between the current temperature measuring voltage and the target temperature voltage is obtained by comparing with the set value in the controller. When the error value is zero, the measured temperature reaches the design temperature, and the heating power does not need to be changed, and the temperature control signal remains unchanged; when this error value is positive, the measured temperature is higher than the design temperature, so it is necessary to reduce the heating power and the temperature control signal. When this error value is negative, the measured temperature is lower than the design temperature, so the heating power needs to be increased, and the temperature control signal keeps increasing. After being processed by the controller, the control quantity is converted into temperature control signals (the signals are voltage signals) by the digital-to-analog converter 11 and input to the voltage-controlled gain amplifier 4 to complete the closed-loop control. The voltage-controlled gain amplifier 4 modulates the amplitude of the 1 MHz oscillation signals based on the temperature control signals. After the amplitude modulation processing by the voltage-controlled gain amplifier 4, the magnitude of the output 1 MHz oscillation signal and the difference between the set temperature value and the air chamber temperature value are related.

The power output module 5 is used to amplify the voltage of the 1 MHz oscillation signals after the amplitude modulation and ensure the stability of the output power when loaded. The power output module is composed of four identical high-frequency power amplifiers. Through the topological circuit, the maximum voltage output and maximum current output of the high-frequency power amplifier may be twice the maximum voltage output and maximum current output under the rated bandwidth.

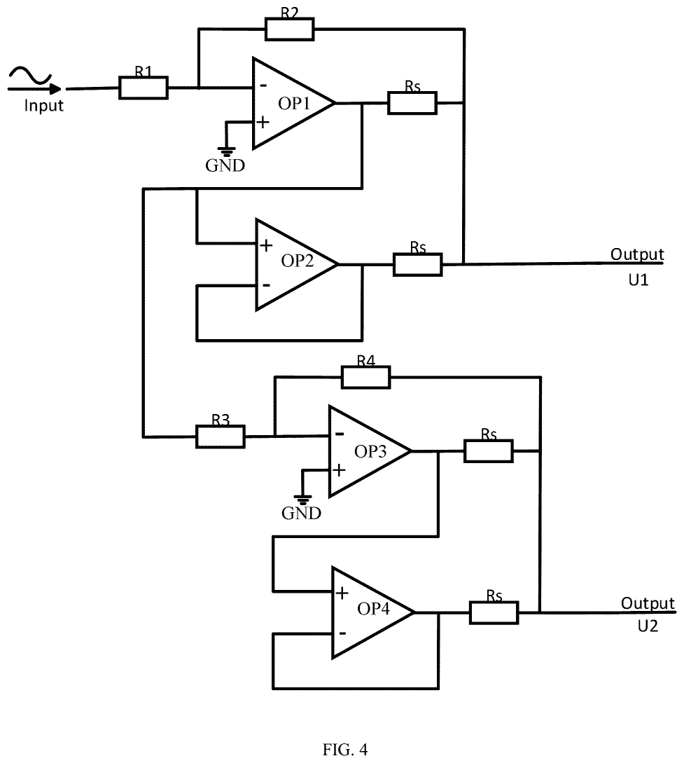

The topology circuit of the power output module 5 provided in this embodiment is as follows: in FIGS. 4, OP1, OP2, OP3 and OP4 are all the same high-frequency power amplifiers. Among them, OP1 and OP3 form a topology loop with voltage, and its working principle is as follows:

The input voltage of OP1 is an oscillation signal after amplitude modulation by a voltage-controlled gain amplifier, and after reverse amplification, the output voltage U₁ is:

$$U = - \frac{{R}_{2}}{{R}_{1}} {U}_{i}$$

where Uᵢ is the sine signal after amplitude modulation of voltage-controlled gain amplifier, and the expression is:

$${U}_{i} = {A}_{i} sin ( {ω}_{i} t + {φ}_{i} )$$

where Aᵢ is the amplitude of the oscillation signal; ωᵢ is the frequency of oscillation signal, which is 1 MHz; φᵢ is the phase error of the oscillating signal. Therefore, the output voltage U₁ of OP1 is:

$${U}_{1} = - \frac{{R}_{2}}{{R}_{1}} {U}_{i} = - \frac{{R}_{2}}{{R}_{1}} {A}_{i} sin ( {ω}_{i} t + {φ}_{i} )$$

where

$$\frac{{R}_{2}}{{R}_{1}} {A}_{i}$$

is the amplitude of the output oscillation signal of OP1, which is limited where by the maximum output voltage of OP1, and the maximum value is U_{MAX}, namely:

$${U}_{1 MAX} = {U}_{MAX}$$

The input voltage of OP3 is the output voltage of OP1. After reverse amplification, the output voltage U₂ is:

$${U}_{2} = \frac{{R}_{2}}{{R}_{3}} \frac{{R}_{2}}{{R}_{1}} {U}_{i} = \frac{{R}_{4}}{{R}_{3}} \frac{{R}_{2}}{{R}_{1}} {A}_{i} sin ( {ω}_{i} t + {φ}_{i} )$$

where R₃ and R₄ choose high-precision resistors with the same resistance value, so the output voltage U₂ is:

$${U}_{2} = \frac{{R}_{2}}{{R}_{1}} {U}_{i} = \frac{{R}_{2}}{{R}_{1}} {A}_{i} sin ( {ω}_{i} t + {φ}_{i} )$$

where

$$\frac{{R}_{2}}{{R}_{1}} {A}_{i}$$

is the amplitude of the oscillation signal output by OP3, which is limited by the maximum output voltage of OP3, and OP3 belongs to the same high-frequency power amplifier as OP1, so the maximum value is U_{MAX}, that is:

$${U}_{3 MAX} = {U}_{MAX}$$

Since OP1 and OP3 are connected to both ends of the load resistor respectively, the voltage Uₒᵤₜ of both ends is:

$${U}_{out} = {U}_{2} - {U}_{1} = \frac{{R}_{2}}{{R}_{1}} {A}_{i} sin ( {ω}_{i} t + {φ}_{i} ) - [ - \frac{{R}_{2}}{{R}_{1}} {A}_{i} sin ( {ω}_{i} t + {φ}_{i} ) ]$$

$${U}_{out} = 2 \frac{{R}_{2}}{{R}_{1}} {A}_{i} sin ( {ω}_{i} t + {φ}_{i} )$$

The maximum amplitude of the oscillation signal output by Vout is:

$${U}_{out MAX} = {U}_{3 MAX} - ( - {U}_{1 MAX} ) = 2 {U}_{MAX}$$

Because the voltage signals at both ends of the load are differentiated, the maximum output voltage of the voltage Uₒᵤₜ at both ends of the load is limited to twice the maximum output voltage limit of the current feedback amplifier, and the topology of the output voltage is completed.

In the topology circuit provided by this embodiment, OP1 and OP2, OP3 and OP4 respectively form the same current topology loop. Taking OP1 and OP2 as examples, the input voltage of OP1 is the oscillation signal Uᵢ after amplitude modulation by a voltage-controlled gain amplifier, and after reverse amplification, the output voltage U₁ is:

$${U}_{1} = - \frac{{R}_{2}}{{R}_{1}} {U}_{i} = - \frac{{R}_{2}}{{R}_{1}} {A}_{i} sin ( {ω}_{i} t + {φ}_{i} )$$

According to the principle of virtual short and virtual break of current feedback amplifier, the current I₁ passing through R₁ is:

$${I}_{1} = \frac{{U}_{i}}{{R}_{1}} = \frac{{A}_{i}}{{R}_{1}} sin ( {ω}_{i} t + {φ}_{i} )$$

The current/load through the load is:

$${I}_{load} = \frac{{U}_{out}}{{R}_{load}} = 2 \frac{{R}_{2}}{{R}_{1} {R}_{load}} {A}_{i} sin ( {ω}_{i} t + {φ}_{i} )$$

where R_{load} is the load resistance, and the resistance is much smaller than R₁, and the ratio of R₂ resistance to R₁ resistance is the amplification factor of OP1 circuit.

OP2 is a voltage follower, the input voltage is the output voltage of OP1, and because Rs is a resistor with the same resistance value, the current Iₛ flowing through Rs is the same, which is:

$${I}_{s} = \frac{{I}_{load} - {I}_{1}}{2} = ( \frac{{R}_{2}}{{R}_{1} {R}_{load}} - \frac{1}{2 {R}_{1}} ) {A}_{i} sin ( {ω}_{i} t + {φ}_{i} )$$

Because the resistance of R is much larger than R_{load}, and the I, is very small, which is 1 uA level, which may be ignored compared with I_{load}, obtaining:

$${I}_{s} \approx \frac{{I}_{load}}{2} = \frac{{R}_{2}}{{R}_{1} {R}_{load}} {A}_{i} sin ( {ω}_{i} t + {φ}_{i} )$$

Therefore, Iₛ is much larger than I₁, and the current limited by the maximum output current of current feedback amplifier is Iₛ, which is determined by the performance and circuit structure of current feedback amplifier at the same time, and its maximum output current I_{sMAX} is:

$${I}_{s MAX} = {I}_{MAX}$$

The maximum output current value L_{loadMAX} of the current I_{load} passing through the load is:

$${I}_{loadMAX} \approx 2 {I}_{sMAX} = 2 {I}_{MAX}$$

At this time, the maximum output current of the current/load flowing through the load is limited to twice the maximum output current limit of the current feedback amplifier, and the topology of the output current is completed.

The coil heating module 6 is a double-layer coil structure with two voltage input ports, which are respectively connected with the output values U₁ and U₂ of the power output module. The resistance is heated by the current in the coil to heat the target gas chamber, and the heating power formula is as follows:

$$W = {( \frac{I}{\sqrt{2}} )}^{2} R$$

where W is the heating power of the coil, I is the amplitude of the sinusoidal current signal, and R is the resistance value of the heating coil. The resistance of the heating coil is constant. When the amplitude of sinusoidal voltage passing through the coil increases, the amplitude of current passing through the coil increases in proportion, and the heating power of the coil increases in proportion at the same time. Therefore, the heating power of the coil may be controlled through the input voltage of the coil.

At the same time, in order to ensure that the current magnetic noise is not introduced in the heating process of the coil, a double-layer symmetrical electric heating film is used as the heating coil.

The above-mentioned embodiment is only a description of the preferred mode of the disclosure, and does not limit the scope of the disclosure. Under the premise of not departing from the design spirit of the disclosure, various modifications and improvements made by ordinary technicians in the field to the technical scheme of the disclosure shall fall within the protection scope determined by the claims of the disclosure.

What is claimed is:

1. A high-power high-frequency electric heating system for a laser optical pump atomic magnetometer, wherein the system is used for heating an alkali gas chamber of the laser optical pump atomic magnetometer, comprising an oscillation generating module, a temperature detecting module, a control module, a power output module and a coil heating module;
wherein the oscillation generating module is used for transmitting 1 MHz oscillation signals; the temperature detecting module is used for measuring a temperature of the alkali metal gas chamber to obtain a differential voltage;
the control module performs an amplitude modulation on the 1 MHz oscillation signals based on the differential voltage to obtain 1 MHz oscillation signals after the amplitude modulation;
the power output module is used for performing voltage amplifying on the 1 MHz oscillation signals after the amplitude modulation and inputting the 1 MHz oscillation signals after the amplitude modulation to the coil heating module, wherein the power output module comprises four identical high-frequency power amplifiers for amplifying a voltage of the 1 MHz oscillation signals after the amplitude modulation; meanwhile, the power output module further completes a maximum voltage output and a maximum current output twice a maximum voltage output and a maximum current output under a rated bandwidth of the high-frequency power amplifiers through a topological circuit; and
the coil heating module is used for heating the alkali metal gas chamber based on a received voltage.

2. The high-power high-frequency electric heating system for the laser optical pump atomic magnetometer according to claim 1, wherein the oscillation generating module comprises a 1 MHz oscillation signal source, a follow-up amplitude modulation circuit and a band-pass filter;
wherein the 1 MHz oscillation signal source is used for transmitting the 1 MHz oscillation signals;
the follow-up amplitude modulation circuit adjusts an amplitude of the 1 MHz oscillation signals; and
the band-pass filter is used for filtering the 1 MHz oscillation signals.

3. The high-power high-frequency electric heating system for the laser optical pump atomic magnetometer according to claim 1, wherein the temperature detecting module comprises a constant current source transmitting device, a four-wire system pt1000 temperature detector and an instrument amplifier resistance detector; the four-wire system pt1000 temperature detector is respectively connected with the constant current source transmitting device and the instrument amplifier resistance detector.

4. The high-power high-frequency electric heating system for the laser optical pump atomic magnetometer according to claim 3, wherein a work flow of the temperature detecting module comprises: transmitting a constant current source by using the constant current source transmitting device and connecting to the four-wire system pt1000 temperature detector, eliminating the line resistance error by using a four-wire system, and finally differentially amplifying the voltages at both ends of the four-wire system pt1000 temperature detector by using the instrument amplifier resistance detector to obtain the differential voltage, thus completing a measurement of an air chamber temperature.

5. The high-power high-frequency electric heating system for the laser optical pump atomic magnetometer according to claim 3, wherein the control module comprises an analog-to-digital converter, a controller, a digital-to-analog converter and a voltage-controlled gain amplifier; the controller is respectively connected with the analog-to-digital converter and the digital-to-analog converter; and the digital-to-analog converter is respectively connected with the voltage-controlled gain amplifier and the analog-to-digital converter.

6. The high-power high-frequency electric heating system for the laser optical pump atomic magnetometer according to claim 5, wherein a work flow of the control module comprises: the differential voltage is analog-to-digital converted by the analog-to-digital converter and then input into the controller; after being processed by the controller, a control quantity is converted into temperature control signals by the digital-to-analog converter to input into the voltage-controlled gain amplifier to complete a closed-loop control; and the voltage-controlled gain amplifier performs an amplitude modulation on the 1 MHz oscillation signals based on the temperature control signals.
